(19) United States
(12) Patent Application Publication
(10) Pub. No.: US 2017/0144251 A1
(43) Pub. Date: May 25, 2017

(54) LASER ANNEALING DEVICE

(71) Applicant: SHANGHAI MICRO ELECTRONICS EQUIPMENT CO., LTD., Shanghai (CN)

(72) Inventors: Chunfeng SONG, Shanghai (CN); Pengli ZHANG, Shanghai (CN); Hailiang LU, Shanghai (CN)

(21) Appl. No.: 15/323,544

(22) PCT Filed: Jul. 3, 2015
(86) PCT No.: PCT/CN2015/083250

§ 371 Date: Jan. 3, 2017

(30) Foreign Application Priority Data
Jul. 4, 2014 (CN) 201410243344.5

(51) Int. Cl. B23K 26/064; B23K 26/70; H01L 21/268; B23K 26/00

(52) U.S. Cl. CPC B23K 26/064; B23K 26/0006; B23K 26/704; H01L 21/268; B23K 2201/40

(57) ABSTRACT

A laser annealing apparatus for annealing a silicon wafer placed on a wafer stage is disclosed which includes: a laser light source for generating a light beam; a first optical unit, configured to convert the light beam generated by the laser light source into a polarized light beam of a first type; and a second optical unit, including a light guiding element and a first reflecting element. The light guiding element is configured to make the polarized light beam of the first type incident on and reflected by a surface of the silicon wafer for a first time along a first optical path, and the light beam reflected from the surface of the silicon wafer is further reflected by the first reflecting element and is thereby incident on the surface of the silicon wafer for a second time along a second optical path symmetrical to the first optical path and reflected by the surface to the light guiding element.

### TECHNICAL FIELD

The present invention relates to the field of semiconductor devices and, in particular, to a laser annealing apparatus for use in an annealing process.

### BACKGROUND

Over the past few decades, the manufacture of electronic devices has undergone rapid development following the Moore's Law. This trend is supported by the increasing shrinkage of integrated circuit (IC) size, which, however, also brings about difficulties and challenges to their manufacturing techniques. Heat treatment has been playing a key role in the fabrication of complementary metal-oxide-semiconductor (CMOS) transistors, especially in some critical procedures such as ultrashallow junction activation and silicide formation. Conventional rapid thermal annealing (RTA) techniques have fallen short of the requirements of the 32-nm node and beyond, and extensive research efforts are underway to develop new annealing techniques to replace RTA, such as flash annealing, laser spike annealing and low temperature solid-phase epitaxy. Among these processes, laser annealing promises a good prospect for application.

In a laser annealing process, a silicon wafer is entirely scanned in such a manner that a laser creates heat in a small area within a relatively short period of time to raise the temperature there to a level that is just below the melting point of the silicon, followed by cooling of the area also in a very short time. The extremely short dwell time of this efficient diffusion-free process on the order of several hundred microseconds (μs) enables the elimination of temperature variations that can serve as driving forces for diffusion before misalignment occurs and hence reduces stress in the wafer. For millisecond annealing, the most concerned yield issues include the involvement of patterns. A wafer being processed bears pattern features including insulating layers and various ion-implanted regions which introduce variations in optical reflectance of films and hence changes in light absorption and heating rate. Some integration schemes utilize absorber layers to compensate for such surface optical properties, which, however, lead to significant increases in process cost and yield risk.

U.S. Patent Pub. No. 2013/0196455A1 discloses maximizing absorption rate at a surface and minimizing difference in light absorption by means of a Brewster angle of incidence of a P-polarized CO₂ laser beam at a wavelength of 10.6 μm. However, this method is limited to the Brewster angle of incidence of a P-polarized beam and therefore needs to be further improved.

### SUMMARY OF THE INVENTION

It is an objective of the present invention to provide a laser annealing apparatus which allows a wider angle of incidence and thus increased surface absorption and reduced difference in light absorption.

It is another objective of the present invention to provide a laser annealing apparatus which is not limited to the incidence of a P-polarized beam and hence has a wider applicability.

These objectives are attained by a laser annealing apparatus for annealing a silicon wafer placed on a wafer stage according to the present invention, which includes: a laser light source, configured to generate a light beam; a first optical unit, configured to convert the light beam generated by the laser light source into a polarized light beam of a first type; and a second optical unit, including a light guiding element and a first reflecting element, wherein the light guiding element is configured to make the polarized light beam of the first type incident on and reflected by a surface of the silicon wafer for a first time along a first optical path, and the reflected light beam from the surface of the silicon wafer is further reflected by the first reflecting element and is thereby incident on the surface of the silicon wafer for a second time along a second optical path symmetrical to the first optical path and reflected by the surface to the light guiding element.

Optionally, the light guiding element may be a polarizing splitter, and the first reflecting element may be a reflector.

Optionally, the second optical unit may further include a ¼ wave plate that is disposed in the second optical path and between the first reflector and the surface of the silicon wafer, and the ¼ wave plate is configured to alter a type of a light beam that is incident on the ¼ wave plate.

Optionally, the second optical unit may further include a second reflector disposed on a side of the polarizing splitter that differs from a side thereof where the polarized light beam of the first type from the first optical unit is incident on the polarizing splitter, and the polarizing splitter is configured to allow a passage of one of a polarized light beam of the first type and a polarized light beam of a second type opposite to the first type and reflect the other one of the polarized light beam of the first type and the polarized light beam of the second type such that a polarized light beam of the second type that has been incident on and reflected by the surface of the silicon wafer and passed through the polarizing splitter is reflected back onto the polarizing splitter by the second reflector.

Optionally, the second reflector may be arranged in parallel with the first optical path; light beam incidence on the polarizing splitter occurs along the first optical path; and the polarizing splitter allows the passage of a polarized light beam of the first type and reflects a polarized light beam of the second type.

Optionally, the second reflector may be arranged perpendicular to the first optical path; light beam incidence on the polarizing splitter occurs in a direction perpendicular to the first optical path; and the polarizing splitter allows the passage of a polarized light beam of the second type and reflects a polarized light beam of the first type.

Optionally, the second optical unit may further include a first lens that is disposed in the first optical path and between the polarizing splitter and the surface of the silicon wafer.

Optionally, the second optical unit may further include a second lens that is disposed in the first optical path and between the ¼ wave plate and the surface of the silicon wafer.

Optionally, the polarized light beam of the first type may pass through the polarizing splitter and the first lens and be then incident on and reflected by the surface of the silicon wafer for a first time, and the first reflected light beam from the surface of the silicon wafer passes through the second lens and the ¼ wave plate and is then reflected by the first reflector; the light beam reflected from the first reflector passes through the ¼ wave plate and the second lens and thereby becomes a polarized light beam of the second type which is incident on and reflected by the surface of the silicon wafer for a second time, and the second reflected light beam from the surface of the silicon wafer passes through the first lens and the polarizing splitter and then is reflected by the second reflector; the light beam reflected from the second reflector passes through the polarizing splitter and the first lens and thereby becomes a polarized light beam of the second type which is incident on and reflected by the surface of the silicon wafer for the third time, and the third reflected light beam from the surface of the silicon wafer passes through the second lens and the ¼ wave plate and then is reflected by the first reflector; and the light beam reflected from the first reflector passes through the ¼ wave plate and the second lens and thereby becomes a polarized light beam of the first type which is incident on and reflected by the surface of the silicon wafer for the fourth time, and the fourth reflected light beam from the surface of the silicon wafer exits the second optical unit after passing through the first lens and the polarizing splitter.

Optionally, the polarized light beam of the first type may be one of a P-polarized light beam and an S-polarized light beam, wherein the polarized light beam of the second type may be the other one of the P-polarized light beam and the S-polarized light beam.

Optionally, the first optical unit may include, sequentially along a path for light beam incidence, an attenuator, a beam collimating and expanding lens group, a beam homogenizer and a polarization adjustment unit.

Optionally, the first optical path may be oriented at an angle of from 30 degrees to 80 degrees relative to the surface of the silicon wafer, with an angle of from 60 degrees to 80 degrees being preferred.

Compared to the prior art, the second optical unit in the laser annealing apparatus according to the present invention functions like an energy compensation unit allowing multiple times of light beam incidence and reflection on the surface of the silicon wafer and hence compensation for reflected light, which results in maximization of surface light absorption and minimization of changes in light absorption. In addition, a light beam, either S- or P-polarized, is allowed to strike the surface of the silicon wafer from the energy compensation unit in a wider range of angles of incidence. This enables the angle of incidence not to be limited to an angle near a particular Brewster angle of incidence while achieving equivalent results. Therefore, the laser annealing apparatus according to the present invention has improved adaptability.

### BRIEF DESCRIPTION OF THE DRAWINGS

FIG. 1 is a schematic illustration of a laser annealing apparatus according to the present invention.

FIG. 2 schematically illustrates an energy compensation unit according to a first embodiment of the present invention.

FIG. 3 depicts variations of dimensionless transmission energy densities with angle of incidence at the same complex index of refraction after difference times of incidence according to the first embodiment of the present invention.

FIG. 4 shows variations of dimensionless transmission energy densities with refractive index under the same angles of incidence according to the first embodiment of the present invention.

FIG. 5 schematically illustrates an energy compensation unit according to a second embodiment of the present invention.

FIG. 6 shows dimensionless transmission energy densities corresponding to different refractive indices according to the second embodiment of the present invention.

FIG. 7 schematically illustrates an energy compensation unit according to a third embodiment of the present invention.

### DETAILED DESCRIPTION

Laser annealing apparatuses according to the present invention will be described in greater detail in the following description which presents preferred embodiments of the invention and is to be read in conjunction with the accompanying drawings. It is to be appreciated that those of skill in the art can make changes in the invention disclosed herein while still obtaining the beneficial results thereof. Therefore, the following description shall be construed as being intended to be widely known by those skilled in the art rather than as limiting the invention.

For simplicity and clarity of illustration, not all features of the disclosed specific embodiment are described. Additionally, descriptions and details of well-known functions and structures are omitted to avoid unnecessarily obscuring the invention. The development of any specific embodiment of the present invention includes specific decisions made to achieve the developer's specific goals, such as compliance with system related and business related constraints, which will vary from one implementation to another. Moreover, such a development effort might be complex and time consuming but would nevertheless be a routine undertaking for those of ordinary skill in the art.

The present invention will be further described in the following paragraphs by way of example with reference to the accompanying drawing. Features and advantages of the invention will be more apparent from the following detailed description, and from the appended claims. Note that the accompanying drawings are provided in a very simplified form not necessarily presented to scale, with the only intention of facilitating convenience and clarity in explaining a few illustrative examples of the invention.

The present invention is based on a core concept that a laser annealing apparatus for annealing a silicon wafer placed on a wafer stage includes a laser light source, an upstream optical unit and an energy compensation unit, wherein the laser light source emits a light beam which is trimmed and converted into a polarized light beam by the upstream optical unit and is incident on the energy compensation unit, and the energy compensation unit makes the incident light beam incident on the silicon wafer for multiple times.

The laser annealing apparatuses according to preferred embodiments will be described below so that the present invention will become clearer. It is to be understood that the present invention is not limited to the embodiments set forth below and that all modifications made by those of ordinary skill in the art using common general technical knowledge are also within the scope of the invention.

The laser annealing apparatuses according to preferred embodiments are based on the concept discussed above. Reference is now made to FIG. 1, which is a schematic illustration of a laser annealing apparatus according to the present invention. As shown in FIG. 1, the apparatus includes: a laser light source 10, an upstream optical unit 200 and an energy compensation unit 60. A silicon wafer 70 is positioned on a wafer stage 80. The laser light source 10 may emit, for example, an infrared, visible or ultraviolet light beam. The light beam is trimmed and converted into a polarized light beam by the upstream optical unit 200 and is then incident on the energy compensation unit 60, and the energy compensation unit 60 makes the incident light beam incident on the silicon wafer 70 for multiple times.

The upstream optical unit 200 may include an attenuator 20, a beam collimating and expanding lens group 30, a beam homogenizer 40 and a polarization adjustment unit 50. As described below with reference to several embodiments, the light beam can be converted into a polarized light beam in a desired form after sequentially passing through those elements.

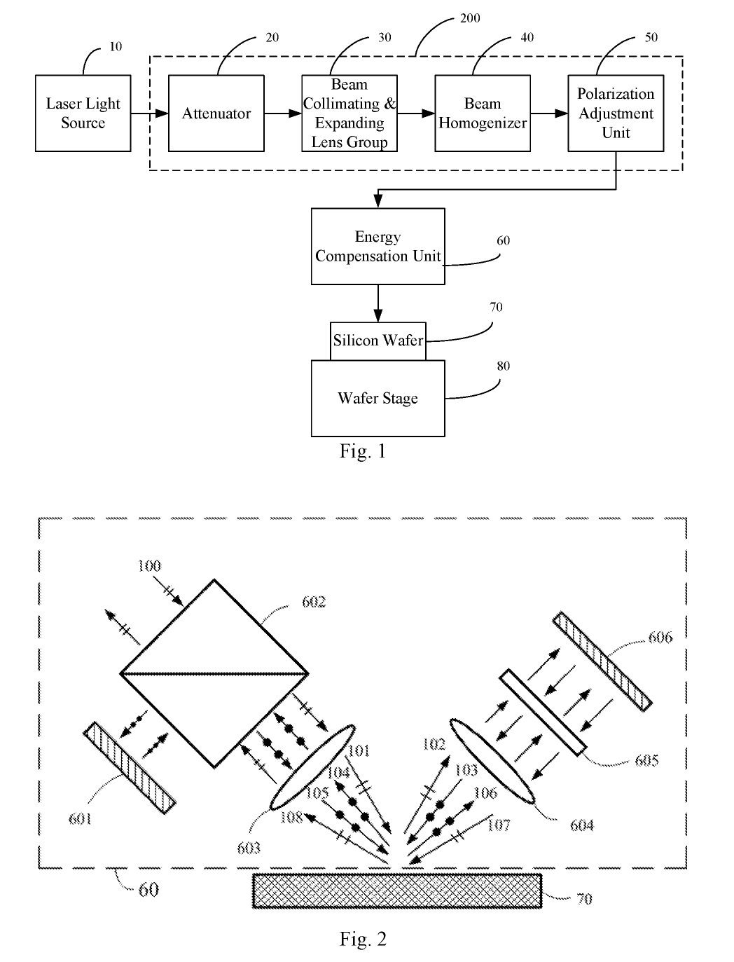

Referring to FIG. 2, an energy compensation unit 60 according to a first embodiment of the present invention includes a polarizing splitter 602, a first lens 603, a second lens 604, a ¼ wave plate 605 and a second reflector 606. After passing through the polarizing splitter 602 and the first lens 603, the light beam is projected onto the silicon wafer 70 and reflected by the silicon wafer 70. The reflected light beam then propagates through the second lens 604 and the ¼ wave plate 605 and is incident on the second reflector 606, wherein the ¼ wave plate is configured to alter a type of the light beam incident on the ¼ wave plate.

The first embodiment of FIG. 2 is a preferred embodiment of the present invention, wherein the energy compensation unit further includes a first reflector 601 disposed on one side of the polarizing splitter 602. Said one side is a side of a line passing through the polarizing splitter 602 and the first lens 603 that is closer to the silicon wafer 70. The polarizing splitter 602 is able to split the incident non-polarized light beam into two linearly polarized, mutually perpendicular light beams which are a P-polarized light beam that passes without loss and an S-polarized light beam that is reflected at an angle of 45 degrees relative to the normal and exits at an angle of 90 degrees relative to the P-polarized light beam.

With continued reference to FIG. 2, the upstream optical unit 200 is so configured that the incident polarized light beam 100 is a P-polarized light beam (each P-polarized light beam is indicated by an arrow with its shaft crossed by two parallel lines) which becomes a P-polarized light beam 101 after passing through the polarizing splitter 602 and the first lens 603. The P-polarized light beam 101 is incident on and reflected by the surface of the silicon wafer 70. The reflected light beam 102 propagates through the second lens 604 and the ¼ wave plate 605 and is then reflected back by the second reflector 606. The reflected light beam passes through the ¼ wave plate 605 and the second lens 604 and thereby becomes an S-polarized light beam 103 (each S-polarized light beam is indicated by an arrow with two dots on its shaft). The S-polarized light beam is again incident on and reflected by the surface of the silicon wafer 70. The reflected light beam 104 is incident on the first lens 603 and the polarizing splitter 602. As the reflected light beam incident on the polarizing splitter 602 is an S-polarized light beam, it is reflected by the polarizing splitter 602 toward the first reflector 601. The reflected light beam exits the splitter at an angle of 90 degrees relative to the direction in which it is incident on the splitter and is further reflected by the first reflector 601.This reflected light beam again propagates through the polarizing splitter 602 and the first lens 603 and thereby becomes an S-polarized light beam 105 which is then incident on and reflected by the surface of the silicon wafer 70 for the third time. The reflected light beam 106 further transmits through the second lens 604 and the ¼ wave plate 605 and is then reflected back by the second reflector 606. This reflected light beam passes through the ¼ wave plate 605 and the second lens 604 and is thereby converted to a P-polarized light beam 107 which is then incident on and reflected by the surface of the silicon wafer 70 for the fourth time. After passing through the first lens 603 and the polarizing splitter 602, the reflected light beam 108 is incident on and transmits through the polarizing splitter 602 due to its P-polarized nature, i.e., leaving from the energy compensation unit.

According to the present invention, the reflections of the incident light beam take place on the surface of the silicon wafer 70 under the conditions as follows: given the refractive index n₀ of the ambient air, refractive index n₁ of the optic material, angle of incidence θ₀ and angle of refraction θ₁, the reflectivity R and transmittance T at the boundary between the media n₀ and n₁ for P- and S-polarized light beams can be respectively calculated according to the Fresnel equations as:

$$\begin{matrix}{R}_{s} = \frac{{sin}^{2} ( {θ}_{0} - {θ}_{1} )}{{sin}^{2} ( {θ}_{0} + {θ}_{1} )} , {T}_{s} = \frac{{n}_{1} cos {θ}_{1}}{{n}_{0} cos {θ}_{0}} \cdot \frac{4 {sin}^{2} {θ}_{1} {cos}^{2} {θ}_{0}}{{sin}^{2} ( {θ}_{0} + {θ}_{1} )} & ( 1 ) \\ {R}_{P} = \frac{{tg}^{2} ( {θ}_{0} - {θ}_{1} )}{{tg}^{2} ( {θ}_{0} + {θ}_{1} )} , {T}_{P} = \frac{{n}_{1} cos {θ}_{1}}{{n}_{0} cos {θ}_{0}} \cdot \frac{4 {sin}^{2} {θ}_{1} {cos}^{2} {θ}_{0}}{{sin}^{2} ( {θ}_{0} + {θ}_{1} ) {cos}^{2} ( {θ}_{1} - {θ}_{1} )} & ( 2 )\end{matrix}$$

where, the angle of incidence and the angle of refraction satisfy n₀/n₁=sin θ₁/sin θ₀, and the subscripts S and P denote S-polarization and P-polarization, respectively.

Assuming the dimensionless transmission energy densities for the schemes with once and four times of incidence are respectively I₁ and I₂, we can obtain from Eqns. (1) and (2):

I₁=Tₚ,

I₂=Tₚ+Rₚ×Tₛ+Rₚ×Rₛ×Tₛ+Rₚ×Rₛ×Rₛ×Tₚ.

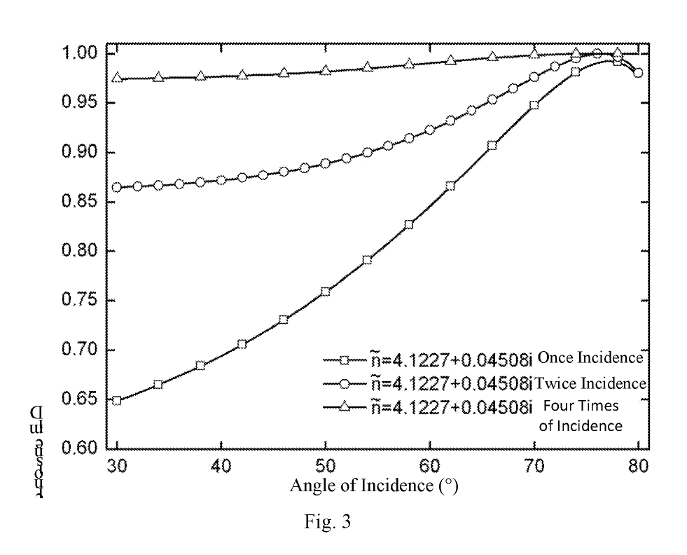

With additional reference to FIG. 3 which depicts curves showing variations of dimensionless transmission energy densities with angle of incidence at the same complex index of refraction for different times of incidence, with the energy compensation unit being used, for any angle of incidence, the surface absorption results of the other two schemes are better than those obtained by the once-incidence design, and the surface absorption results of the scheme with four times of incidence are better than those of the scheme with twice incidence. In the present embodiment, the angle of incidence that has been tested is within the range of from 30° to 80°. For example, if the light beam is incident at an angle of 45° with a variation within the range of ±1°, surface absorption fluctuation (each defined as the ratio of the difference between the maximum and minimum dimensionless transmission energy densities to the sum of them at the angle of incidence between 44° and 46°) for the once-incidence scheme is 0.889%, surface absorption fluctuation for the twice-incidence scheme is 0.189% and surface absorption fluctuation for the four-times-incidence scheme is 0.052%. As another example, for an angle of incidence of 60° with a variation within the range of ±1°, surface absorption fluctuation for the once-incidence scheme is 1.152%, surface absorption fluctuation for the twice-incidence scheme is 0.484% and surface absorption fluctuation for the four-times-incidence scheme is 0.095%. Therefore, compensation for the silicon wafer with light collected by the energy compensation unit results in higher resilience to fluctuations in angle of incidence compared to cases not using the energy compensation unit, and the resilience after three times of compensation (i.e., four times of incidence) is better than that after once compensation (i.e., twice incidence). The thrice compensation enabled by collection of reflected light using the energy compensation unit can maximize surface absorption and thus facilitate the annealing. Despite the fact that the theoretical maximum surface absorption can be achieved by aligning the angle of incidence with the Brewster angle of incidence, according to this embodiment, by means of reflection compensation, even when the angle of incidence is not strictly controlled to be near a Brewster angle of incidence, acceptable surface absorption can be obtained and hence a higher adaptability.

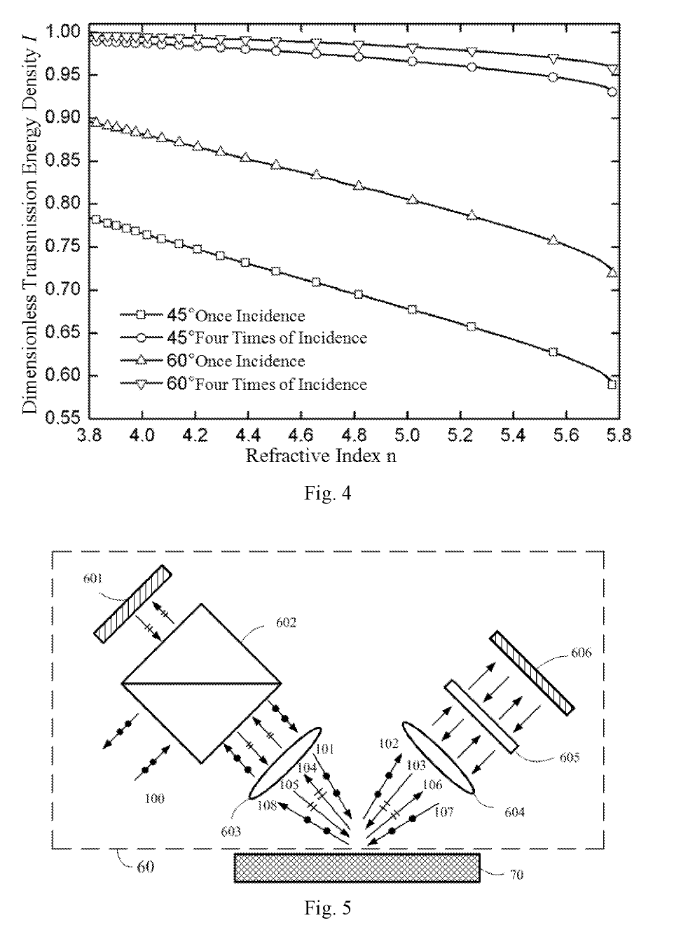

With additional reference to FIG. 4 which shows curves illustrating variations of dimensionless transmission energy densities with refractive index under the same angles of incidence, for each of the two given angles of incidence, the four times of incidence enabled by the energy compensation unit corresponds to significantly increased dimensionless transmission energy densities compared to the once-incidence scheme, as well as attenuated changes in in light absorption with optic material refractive index. In both the two extreme cases with the maximum and minimum refractive indices, surface absorption fluctuation for the once-incidence scheme is 14.66% and surface absorption fluctuation for the four-times-incidence scheme is 3.13% with an angle of incidence of 45°. Surface absorption fluctuation for the once-incidence scheme is 11.28% and surface absorption fluctuation for the four-times-incidence scheme is 1.99% with an angle of incidence of 60°. Therefore, the design with four times of incidence can, on one hand, increase light adsorption and, on the other hand, reduce light adsorption fluctuations caused by difference in optical properties. Considering the angle of incidence of 60° can result in better results than 45°, a great angle of incidence, such as those within the range of from 60° to 80°, is preferred for the laser annealing apparatus in practical applications.

With reference to FIG. 5 which shows a second embodiment of the present invention which is another preferred embodiment, wherein for the sake of simplicity, modules identical or similar to those of the first embodiment are referenced with identical numerals and are not described again to avoid duplicate explanation. Differing from the first embodiment, the first reflector 601 is disposed on the line passing through the polarizing splitter 602 and the first lens 603 and on the side away from the first lens 603. The upstream optical unit 200 is so configured that the incident polarized light beam 100 is an S-polarized light beam which becomes an S-polarized light beam 101 after passing through the polarizing splitter 602 and the first lens 603. The S-polarized light beam 101 is incident on and reflected by the surface of the silicon wafer 70. The reflected light beam 102 propagates through the second lens 604 and the ¼ wave plate 605 and is then reflected back by the second reflector 606. This reflected light beam passes through the ¼ wave plate 605 and the second lens 604 and thereby becomes a P-polarized light beam 103 which is again incident on and reflected by the surface of the silicon wafer 70. After passing through the first lens 603 and the polarizing splitter 602, the reflected light beam 104 is reflected by the first reflector 601 and is converted to a P-polarized light beam 105 after transmitting through the polarizing splitter 602 and the first lens 603. The P-polarized light beam 105 is then incident on and reflected by the surface of the silicon wafer 70 for the third time. After passing through the second lens 604 and the ¼ wave plate 605, the reflected light beam 106 is reflected back by the second reflector 606. This reflected light beam again propagates through the ¼ wave plate 605 and the second lens 604 and thereby becomes an S-polarized light beam 107 which is then incident on and reflected by the surface of the silicon wafer 70 for the fourth time. This reflected light beam 108 subsequently passes through the first lens 603 and the polarizing splitter 602, exiting the energy compensation unit.

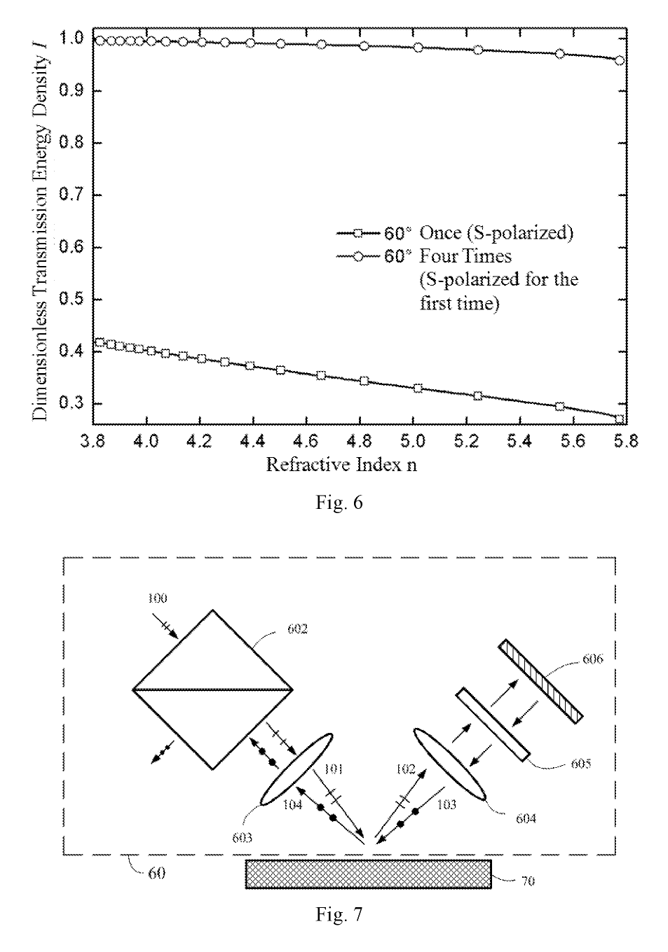

With additional reference to FIG. 6 which shows curves of dimensionless transmission energy densities corresponding to different refractive indices, after the S-polarized light beam is incident on the energy compensation unit, a comparison between the results obtained by the four times of incidence with those by once incidence reveals that absorption for the surface of the silicon wafer is increased by at least two times. Besides, under the two extreme conditions, i.e., the maximum and minimum refractive indices, surface absorption fluctuation for the once-incidence scheme is 22.5% and surface absorption fluctuation for the four-times-incidence scheme is 1.99%. In addition, in this four-times-incidence design, the polarization of the light beam incident on the energy compensation unit for the first time has no impact on the final results.

With reference to FIG. 7 which shows a third embodiment of the present invention, wherein for the sake of simplicity, modules identical or similar to those of the first embodiment are referenced with identical numerals and are not described again to avoid duplicate explanation. In this embodiment, the incident polarized light beam 100 is a P-polarized light beam which is shaped into a P-polarized light beam 101 by passing through the polarizing splitter 602 and the first lens 603. The P-polarized light beam 101 is incident on and reflected by the surface of the silicon wafer 70, and the light beam 102 reflected from the surface further propagates through the second lens 604 and the ¼ wave plate 605 and is then reflected by the second reflector 606. The reflected light beam then transmits through the ¼ wave plate 605 and the second lens 604 and thereby becomes an S-polarized light beam 103 which is again incident on and reflected by the surface of the silicon wafer 70. Subsequently, the reflected light beam 104 exits the energy compensation unit after passing through the first lens 603 and the polarizing splitter 602.

According to this embodiment, the energy compensation unit is simplified and the number of times of light beam reflection occurring on the surface of the silicon wafer is accordingly reduced. However, it can be easily found when referencing the first embodiment that the once-compensation design according to this embodiment still achieves better results compared to the once-reflection scheme.

It is apparent that those skilled in the art can make various modifications and variations to the present invention without departing from the spirit and scope thereof. Accordingly, it is intended that the invention embraces all such modifications and variations as fall within the scope of the appended claims and equivalents thereof.

1. A laser annealing apparatus for annealing a silicon wafer placed on a wafer stage, comprising:
a laser light source, configured to generate a light beam;
a first optical unit, configured to convert the light beam generated by the laser light source into a polarized light beam of a first type; and
a second optical unit, comprising a light guiding element and a first reflecting element, wherein the light guiding element is configured to make the polarized light beam of the first type incident on and reflected by a surface of the silicon wafer for a first time along a first optical path; and the reflected light beam from the surface of the silicon wafer is further reflected by the first reflecting element and is thereby incident on the surface of the silicon wafer for a second time along a second optical path symmetrical to the first optical path and reflected by the surface of the silicon wafer to the light guiding element.

2. The laser annealing apparatus of claim 1, wherein the light guiding element is a polarizing splitter and the first reflecting element is a reflector.

3. The laser annealing apparatus of claim 2, wherein the second optical unit further comprises a ¼ wave plate disposed in the second optical path and between the first reflector and the surface of the silicon wafer, and the ¼ wave plate is configured to alter a type of a light beam that is incident on the ¼ wave plate.

4. The laser annealing apparatus of claim 3, wherein the second optical unit further comprises a second reflector disposed on a side of the polarizing splitter that differs from a side thereof where the polarized light beam of the first type from the first optical unit is incident on the polarizing splitter; and the polarizing splitter is configured to allow a passage of one of a polarized light beam of the first type and a polarized light beam of a second type opposite to the first type and reflect the other one of the polarized light beam of the first type and the polarized light beam of the second type such that a polarized light beam of the second type that has been incident on and reflected by the surface of the silicon wafer and passed through the polarizing splitter is reflected back onto the polarizing splitter by the second reflector.

5. The laser annealing apparatus of claim 4, wherein: the second reflector is arranged in parallel with the first optical path; a light beam incidence on the polarizing splitter occurs along the first optical path; and the polarizing splitter allows the passage of a polarized light beam of the first type and reflects a polarized light beam of the second type.

6. The laser annealing apparatus of claim 4, wherein: the second reflector is arranged perpendicular to the first optical path; a light beam incidence on the polarizing splitter occurs in a direction perpendicular to the first optical path; and the polarizing splitter allows the passage of a polarized light beam of the second type and reflects a polarized light beam of the first type.

7. The laser annealing apparatus of claim 3, wherein the second optical unit further comprises a first lens disposed in the first optical path and between the polarizing splitter and the surface of the silicon wafer.

8. The laser annealing apparatus of claim 7, wherein the second optical unit further comprises a second lens disposed in the first optical path and between the ¼ wave plate and the surface of the silicon wafer.

9. The laser annealing apparatus of claim 8, wherein: the polarized light beam of the first type passes through the polarizing splitter and the first lens and is then incident on and reflected by the surface of the silicon wafer for a first time, and the first reflected light beam from the surface of the silicon wafer passes through the second lens and the ¼ wave plate and is then reflected by the first reflector; the light beam reflected from the first reflector passes through the ¼ wave plate and the second lens and thereby becomes a polarized light beam of the second type which is incident on and reflected by the surface of the silicon wafer for a second time, and the second reflected light beam from the surface of the silicon wafer passes through the first lens and the polarizing splitter and then is reflected by the second reflector; the light beam reflected from the second reflector passes through the polarizing splitter and the first lens and thereby becomes a polarized light beam of the second type which is incident on and reflected by the surface of the silicon wafer for a third time, and the third reflected light beam from the surface of the silicon wafer passes through the second lens and the ¼ wave plate and then is reflected by the first reflector; and the light beam reflected from the first reflector passes through the ¼ wave plate and the second lens and thereby becomes a polarized light beam of the first type which is incident on and reflected by the surface of the silicon wafer for a fourth time, and the fourth reflected light beam from the surface of the silicon wafer exits the second optical unit after passing through the first lens and the polarizing splitter.

10. The laser annealing apparatus of claim 4, wherein the polarized light beam of the first type is one of a P-polarized light beam and an S-polarized light beam; and the polarized light beam of the second type is the other one of the P-polarized light beam and the S-polarized light beam.

11. The laser annealing apparatus of claim 1, wherein the first optical unit comprises, sequentially along a path for light beam incidence, an attenuator, a beam collimating and expanding lens group, a beam homogenizer and a polarization adjustment unit.

12. The laser annealing apparatus of claim 1, wherein the first optical path is oriented at an angle of from 30 degrees to 80 degrees relative to the surface of the silicon wafer.

13. The laser annealing apparatus of claim 12, wherein the first optical path is oriented at an angle of from 60 degrees to 80 degrees relative to the surface of the silicon wafer.
